(19) United States
(12) Patent Application Publication
(10) Pub. No.: US 2019/0100429 A1
(43) Pub. Date: Apr. 4, 2019

(54) MEMS DEVICES AND PROCESSES

(71) Applicant: Cirrus Logic International Semiconductor Ltd., Edinburgh (GB)

(72) Inventors: Tom HANLEY, Edinburgh (GB); Colin Robert JENKINS, Linlithgow (GB); Euan James BOYD, Edinburgh (GB)

(73) Assignee: Cirrus Logic International Semiconductor Ltd., Edinburgh (GB)

(21) Appl. No.: 16/140,585

(22) Filed: Sep. 25, 2018

Related U.S. Application Data
(60) Provisional application No. 62/565,151, filed on Sep. 29, 2017.

(30) Foreign Application Priority Data
Oct. 23, 2017 (GB) 1717385.7

(51) Int. Cl. B81B 7/02; H04R 19/04; B81C 1/00

(52) U.S. Cl. CPC B81B 7/02; H04R 19/04; B81C 1/00166; B81B 2207/09; B81B 2203/0127; B81B 2203/04; B81B 2201/0257

(57) ABSTRACT

A MEMS transducer and method of forming a MEMS transducer. The MEMS transducer comprises a flexible membrane and a backplate, a membrane electrode being located on a polygon shaped first surface of the flexible membrane, and a backplate electrode being located on a first surface of the backplate facing the membrane electrode. At least one of the membrane electrode and the backplate electrode has an outline shape configured to correspond to a contour of a contour map, the contour map representing relative amounts of displacement of portions of the flexible membrane from an equilibrium position in response to pressure differences generated by incident sound waves.

### TECHNICAL FIELD

This application relates to micro-electro-mechanical system (MEMS) devices and processes, and in particular to a MEMS device and process relating to a transducer, for example a capacitive microphone.

### BACKGROUND INFORMATION

MEMS devices are becoming increasingly popular. MEMS transducers, and especially MEMS capacitive microphones, are increasingly being used in portable electronic devices such as mobile telephone and portable computing devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing. A substrate supports at least the membrane(s) and typically the backplate also. In the case of MEMS pressure sensors and microphones the read out is usually accomplished by measuring the capacitance between the membrane and backplate electrodes. In the case of transducers, the device is driven, i.e. biased, by a potential difference provided across the membrane and backplate electrodes.

FIGS. 1A and 1B show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1A the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110. A plurality of holes, hereinafter referred to as bleed holes 111, connect the first cavity 109 and the second cavity 110. The bleed holes act to equalise the pressure between the first cavity 109 and the second cavity 110, and may also be referred to as pressure equalisation holes.

A plurality of acoustic holes 112 are arranged in the back-plate 104 so as to allow free movement of air molecules through the back plate, such that the second cavity 110 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume being referred to as a “back volume”. Typically, for MEMS microphones and the like, the first and second volumes are connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like.

In some applications the backplate may be arranged in the front volume, so that incident sound reaches the membrane via the acoustic holes 112 in the backplate 104. In such a case the substrate cavity 108 may be sized to provide at least a significant part of a suitable back-volume. In other applications, the microphone may be arranged so that sound may be received via the substrate cavity 108 in use, i.e. the substrate cavity forms part of an acoustic channel to the membrane and part of the front volume. In such applications the backplate 4 forms part of the back-volume which is typically enclosed by some other structure, such as a suitable package.

It should also be noted that whilst FIGS. 1A and 1B shows the backplate being supported on the opposite side of the membrane to the substrate, arrangements are known where the backplate is formed closest to the substrate with the membrane layer supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown).

The membrane layer and thus the flexible membrane of a MEMS transducer generally comprises a thin layer of a dielectric material—such as a layer of crystalline or polycrystalline material. The membrane layer may, in practice, be formed by several layers of material which are deposited in successive steps. Thus, the flexible membrane 101 may, for example, be formed from silicon nitride Si₃N₄ or polysilicon. Crystalline and polycrystalline materials have high strength and low plastic deformation, both of which are highly desirable in the construction of a membrane.

The membrane electrode 102 of a MEMS transducer is typically a thin layer of metal, e.g. aluminium, which is typically located in the centre of the flexible membrane 101. The centre of the membrane is the part of the membrane which typically displaces the most due to incident pressure waves. It will be appreciated by those skilled in the art that the membrane electrode may be formed by depositing a metal alloy such as aluminium-silicon for example. The membrane electrode may typically cover, for example, around 40% of area of the membrane, usually in the central region of the membrane. The membrane electrode is typically of the same outline shape as the flexible membrane upon which the membrane electrode is located; for example, a circular flexible membrane would typically have a circular membrane electrode, as shown in FIGS. 1A and 1B.

In order to allow the displacement of the flexible membrane to be monitored, capacitive microphones comprise systems for monitoring the variation in capacitance between the electrode on the flexible membrane and the electrode on the backplate, as discussed above. The sensitivity of the capacitive microphone is proportional to the change in capacitance (caused by changes in the separation between the electrodes due to movement of the flexible membrane) divided by the total capacitance. Although increasing the amount of electrode material, typically a thin layer of metal, on the flexible membrane can increase the absolute change in capacitance for a given flexible membrane movement, increasing the amount of electrode material can also increase the total capacitance and reduce the flexibility of the membrane, thereby negatively impacting upon the capacitive microphone performance.

The present disclosure relates to MEMS transducers comprising flexible membranes, the flexible membranes comprising membrane electrodes, wherein the membrane electrodes are configured to optimise the electrodes to maximise the variation in capacitance with flexible membrane movement (for a given total capacitance), and thereby provide the best possible capacitive sensitivity for a given electrode area.

### SUMMARY

According to an embodiment of an aspect there is provided a MEMS transducer comprising a flexible membrane and a backplate, a membrane electrode being located on a polygon shaped first surface of the flexible membrane, and a backplate electrode being located on a first surface of the backplate facing the membrane electrode, wherein at least one of the membrane electrode and the backplate electrode has an outline shape configured to correspond to a contour of a contour map, the contour map representing relative amounts of displacement of portions of the flexible membrane from an equilibrium position in response to pressure differences generated by incident sound waves. Matching the outline shape of the electrode to a contour of the contour map allows the capacitive sensing capabilities of a capacitor formed using the membrane electrode and backplate electrode to be optimised. This is particularly the case where the outline shape corresponds to a contour representing points of the flexible membrane of equal displacement from the equilibrium position.

The MEMS transducer may further comprise a substrate and a membrane layer, the membrane layer comprising the flexible membrane. Further, the perimeter of the flexible membrane may be defined by a fixed edge of the flexible membrane connected to the substrate, or the membrane layer may comprise one or more slits which border unfixed edges of the flexible membrane, such that the perimeter of the flexible membrane is defined by one or more fixed edges of the flexible membrane connected to the substrate and one or more unfixed edges of the flexible membrane. Use of only fixed edges, or a combination of fixed and unfixed edges, allows the MEMS transducer to be adapted to be suitable to a broad range of applications.

The first surface of the flexible membrane may be rectangular (including square), or may be octagonal. When the first surface of the flexible membrane is an octagon, this octagon may have edges of a first length and edges of a second length, the edges of the first length and the edges of the second length alternating around the perimeter of the first surface of the flexible membrane. Rectangular (including square) flexible membranes can maximise the flexible membrane area relative to the area on the chip available for the flexible membrane, while octagonal flexible membranes can be particularly resilient.

Where the membrane electrode has an outline shape configured to correspond to the contour of the contour map, the outline shape of the membrane electrode may be selected such that the volume displaced by the membrane electrode, when the maximum membrane displacement distance from an equilibrium position is 10% of the mean diameter of the first surface of the flexible membrane, is at least 80% of the volume displaced by an identical electrode displaced pistonically by the maximum membrane displacement distance. This allows an optimal balance of membrane area and electrode shape to allow good sensing behaviour.

The contour map may represent the relative amounts of displacement of portions of the flexible membrane from the equilibrium position in response to pressure differences generated by sound waves having a frequency which is lower than the fundamental resonant frequency of the flexible membrane, or the displacement in response to pressure differences generated by sound waves having a frequency which is equal to or higher than the fundamental resonant frequency of the flexible membrane. In this way, the membrane can be optimised for intended use.

According to further embodiments of aspects there are provided:
a MEMS transducer comprising: a polygon shaped flexible membrane; and a membrane electrode located on a surface of the flexible membrane, wherein the membrane electrode is shaped to substantially correspond to a contour of a contour map, the contour map representing relative amounts of displacement of portions of the flexible membrane from an equilibrium position in response to incident pressure waves,
a MEMS transducer comprising: a polygon shaped flexible membrane; a backplate; and a backplate electrode located on a surface of the backplate facing the flexible membrane, wherein the backplate electrode is shaped to substantially correspond to a contour of a contour map, projected onto the backplate, the contour map representing relative amounts of displacement of portions of the flexible membrane from an equilibrium position in response to incident pressure waves, and
a MEMS transducer comprising: a polygon shaped flexible membrane; a backplate; a membrane electrode; and a backplate electrode located on a surface of the backplate facing the flexible membrane, wherein the membrane electrode is shaped to substantially correspond to a contour of a contour map, the contour map representing relative amounts of displacement of portions of the flexible membrane from an equilibrium position in response to incident pressure waves, and wherein the backplate electrode is shaped to substantially correspond to a contour of the contour map, projected onto the backplate. Matching the shape of one or both of the membrane electrode and the backplate electrode to a contour of the contour map allows the capacitive sensing capabilities of a capacitor formed using at least one of the electrodes to be optimised.

According to a further embodiment of an aspect there is provided a method of forming a MEMS transducer comprising a flexible membrane and a backplate, a membrane electrode being located on a polygon shaped first surface of the flexible membrane, and a backplate electrode being located on a first surface of the backplate facing the membrane electrode, the method comprising:
simulating the flexible membrane of the MEMS transducer;
modelling the displacement of the simulated flexible membrane in response to pressure differences generated by incident sound waves;
producing a contour map representing relative amounts of displacement of portions of the flexible membrane from an equilibrium position in response to pressure differences generated by incident sound waves;
designing an outline shape of at least one of the membrane electrode and the backplate electrode to correspond to a contour of the contour map; and
producing the MEMS transducer in accordance with the design. The method of forming allows the production of MEMS transducers wherein the capacitive sensing capabilities of a capacitor formed using the membrane electrode and backplate electrode can be optimised.

Features of any given aspect may be combined with the features of any other aspect and the various features described herein may be implemented in any combination in a given embodiment.

Associated methods of fabricating a MEMS transducer are provided for each of the above aspects and examples described herein.

### FIGURES

The invention is described, by way of example only, with reference to the following Figures, in which:

FIG. 1A is a schematic view of a known MEMS capacitive microphone device.

FIG. 1B is a perspective view of a known MEMS capacitive microphone device.

FIG. 2A is a cross section illustrating the displacement of a flexible membrane that is fixed at edge locations.

FIG. 2B is a cross section illustrating the pistonic displacement of an idealised flexible membrane.

FIG. 2C is a perspective view of the membrane electrode of FIG. 2A.

FIG. 2D is a perspective view of the membrane electrode of FIG. 2B.

FIG. 3A is a plot of a simulated square flexible membrane displacement.

FIG. 3B is a contour map corresponding to FIG. 3A.

FIG. 3C is an optimised electrode outline shape based on the contour map of FIG. 3B.

FIG. 3D is a plot of a simulated octagonal flexible membrane displacement.

FIG. 3E is a contour map corresponding to FIG. 3D.

FIG. 3F is an optimised electrode outline shape based on the contour map of FIG. 3E.

FIG. 4A is a plot of a simulated complex shaped flexible membrane displacement.

FIG. 4B is a contour map corresponding to FIG. 4A.

FIG. 4C is an optimised electrode outline shape based on the contour map of FIG. 4B.

FIG. 5A is a plot of simulate flexible membrane displacement for a flexible membrane having fixed and unfixed edges.

FIG. 5B is a contour map corresponding to FIG. 5A.

FIG. 5C1 is an optimised electrode outline shape based on the contour map of FIG. 5B.

FIG. 5C2 is a further optimised electrode outline shape based on the contour map of FIG. 5B.

FIG. 6A is a diagram illustrating electrical field lines between a flat backplate electrode and a curved membrane electrode.

FIG. 6B is a diagram illustrating electrical field lines between a flat backplate electrode and a flat membrane electrode.

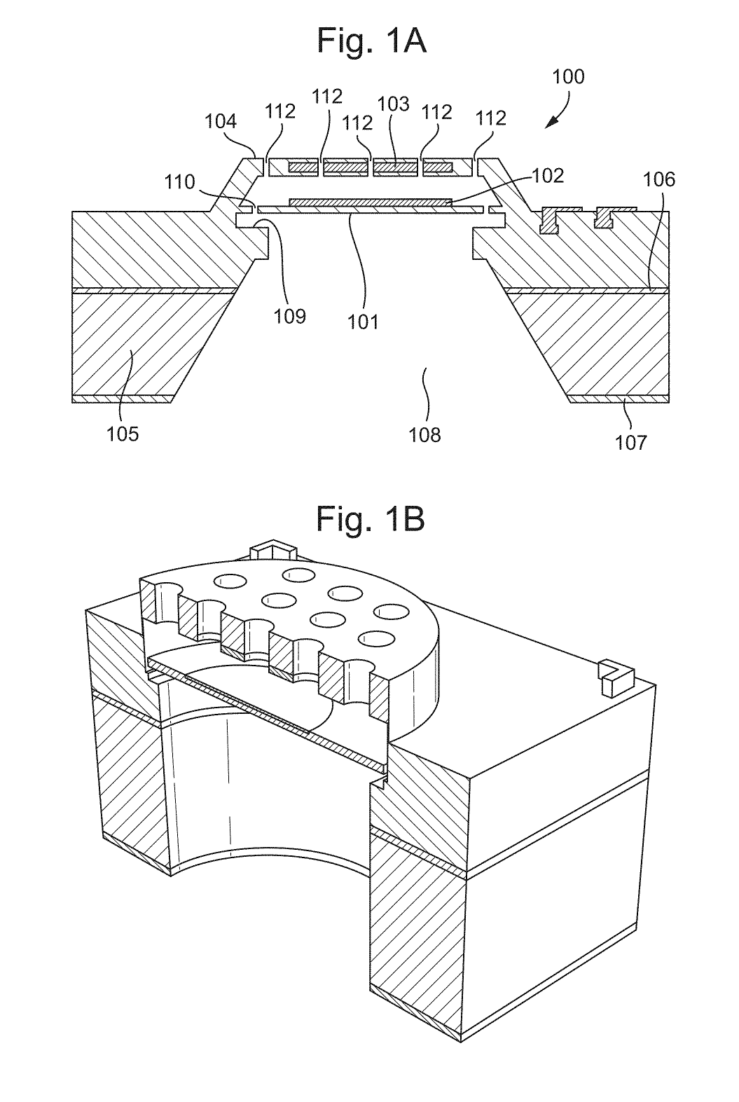

### DETAILED DESCRIPTION

A flexible membrane is typically key to a MEMS device configured as a sensing apparatus, for example a microphone. The flexible membrane may be formed as part of a larger membrane layer, and the shape of the flexible membrane may be determined by the shape of the connection between the flexible membrane and the rest of the membrane layer, that is, where the membrane layer is connected to a substrate of the MEMS transducer. The flexible membrane can be formed such that the first surface of the flexible membrane has any shape, determined by the particular requirements of a given MEMS transducer in a MEMS device configured to operate as a microphone. For example, a flexible membrane having a square shape (such that the surface facing a backplate electrode is square) may be used, in order to maximise the sensing surface area relative to the total area occupied by the MEMS device.

When pressure waves (such as sound waves) cause the deflection (displacement) of the flexible membrane from an equilibrium (or quiescent) position, the amount of displacement is not uniform across the flexible membrane. This is because the edge of the flexible membrane is held in a fixed position around at least a part of the flexible membrane perimeter, and in some examples around the entirety of the flexible membrane perimeter, and therefore the membrane displacement in response to an incident pressure wave is restricted. Accordingly, the amount of displacement of a given point on the flexible membrane from an equilibrium position is partially determined by the separation of the given point from fixed edges of the flexible membrane.

Typically, membrane electrodes are formed with the same outline shape as the flexible membrane (so a square flexible membrane would include a square membrane electrode). Using a membrane electrode of the same outline shape as the flexible membrane allows the area of the flexible membrane surface occupied by the membrane electrode to be maximised (which can help increase the variation in capacitance with displacement of the capacitive monitoring system and can also assist in providing a predictable membrane response to incident pressure waves). However, the most efficient form of membrane electrode displacement for capacitive variation sensing (and hence microphone sensitivity) is pistonic displacement. Pistonic displacement refers to an idealised situation where the entirety of the electrode is deflected by an equal amount relative to an equilibrium position (such that the electrode remains flat when deflected). For a flexible membrane having edge(s) held in a fixed position (as discussed above), it is not possible for the entire flexible membrane to displace pistonically; the fixed edge or edges mean that the amount of displacement will always vary across the membrane surface. Accordingly, pistonic displacement is an idealised version of a real world situation.

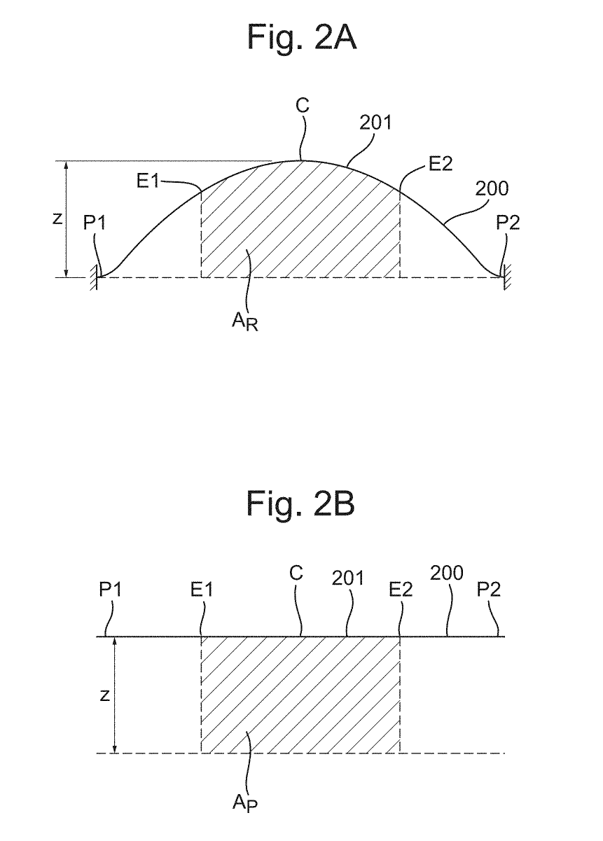

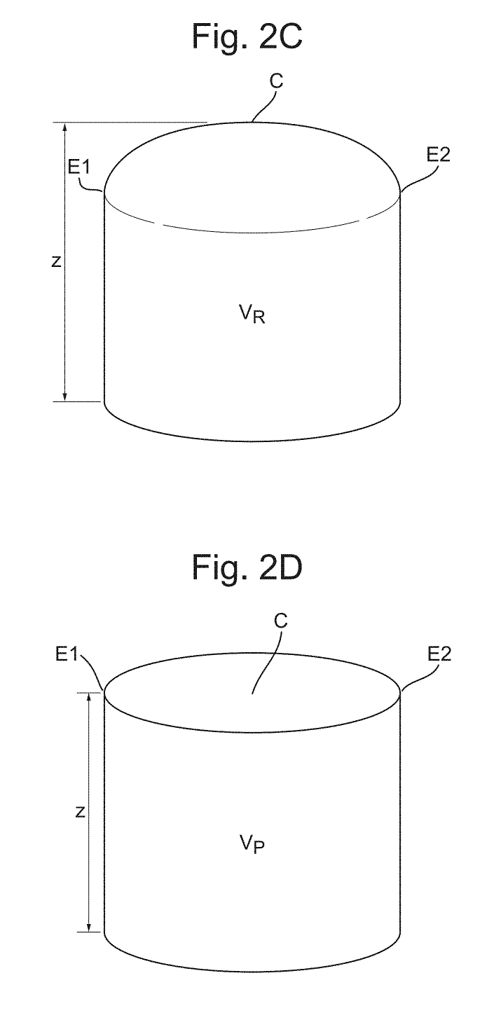

FIGS. 2A and 2B are cross sections across flexible membranes, and illustrate the difference in the displacement of a real flexible membrane (FIG. 2A), and an idealised flexible membrane behaving pistonically (FIG. 2B), in response to a given incident pressure wave. The flexible membranes 200 in FIGS. 2A and 2B are the same size and shape, when in a quiescent (equilibrium) position. For simplicity, the flexible membranes 200 shown in cross section in FIGS. 2A and 2B are circular, such that the edges of the flexible membranes 200 are separated from the centres C of the membranes 200 by an equal amount (the radii of the circular flexible membranes 200) around the entire perimeters of the flexible membranes 200.

In FIG. 2A, the flexible membrane 200 is fixed at positions P1 and P2; the flexible membrane 200 at these points cannot displace in response to an incident pressure wave. As a result, the overall cross section profile of the displaced flexible membrane 200 in FIG. 2A is dome shaped, with the maximum displacement of the membrane at the centre C of the membrane. At point C, the total distance by which the flexible membrane 200 has displaced relative to the equilibrium position is z.

In FIG. 2B, the (idealised) flexible membrane 200 displaces pistonically. Accordingly, the membrane surface remains flat when displaced. The displacement at the centre C of the flexible membrane 200 is the same as that at the edges of the flexible membrane 200, at points P1 and P2; all of these points displace by distance z relative to their respective equilibrium positions.

Both FIG. 2A and FIG. 2B shown the location of the membrane electrode 201. In the cross sections shown, the membrane electrode 201 extends from point E1 to point E2 (via the centre C of the membrane 200). The shaded area on FIGS. 2A and 2B shows the cross section area displaced by the electrode 201 when the flexible membrane 200 displaces. Area A_{R} as shown in FIG. 2A shows the area displaced by the electrode of the real flexible membrane 200 (fixed at points P1 and P2) in that figure. Area A_{P} as shown in FIG. 2B shows the area displaced by the electrode 201 of the idealised flexible membrane 200 in that figure which displaces pistonically.

FIGS. 2C and 2D show perspective views of the flexible membranes of FIGS. 2A and 2B respectively. When the displacement of the membrane is considered in three dimensions, the respective quantities are the volume V_{R} displaced by the real flexible membrane (shown in FIG. 2C), and the volume V_{P} displaced by the pistonic membrane (shown in FIG. 2D). As illustrated by FIGS. 2C and 2D, V_{R} will be less than V_{P}, because the curvature of the flexible membrane means that the points on the flexible membrane further from the centre C for the real flexible membrane will displace less than the equivalent points in the idealised pistonic membrane (wherein all of the points on the membrane will displace by an equivalent amount, displacement z in the FIG. 2B example).

It is possible to define how closely the displacement of a real membrane electrode corresponds to that of an idealised pistonic displacement by considering the “flatness” of the electrode when displaced. A flatness value F for a given membrane electrode on a given flexible membrane can be obtained by dividing the volume displaced by the electrode V_{R} by the volume displaced by an identical electrode moving pistonically V_{P}; F=V_{R}/V_{P}. For example, if the curvature of a flexible membrane of given dimensions under displacement means that the value of V_{R} is 60% of the value of V_{P}, then the flatness value F for the given membrane electrode on the given flexible membrane would be 0.6. Preferably a flatness value of at least 0.8 is provided by an optimised flexible membrane outline shape when the maximum membrane displacement distance from an equilibrium position is 10% of the mean diameter of the first surface of the flexible membrane. This equates to a V_{R} value that is at least 80% of the value of V_{P}.

From FIGS. 2A to 2D, it is clear that the flatness of the electrode could be maximised by reducing the area of the electrode, such that the electrode was concentrated at the centre of the flexible membrane and the curvature of the flexible membrane has a limited effect on the value of V_{R}. However, the total capacitance is proportional to the area of the membrane electrode (and of a corresponding backplate electrode), so reducing the area of the electrode will result in a reduction in the absolute capacitance variation (for a given flexible membrane displacement). Therefore it is desirable to provide an electrode shape which maximises the flatness of the electrode, for a given electrode area and given flexible membrane shape, and thereby maximises the capacitance variation with flexible membrane deflection for a given total capacitance.

In order to maximises the flatness of the electrode, for a given electrode area and given flexible membrane shape, the membrane electrode may be formed so as to follow the contours of displacement of the membrane. In order to do this, it is first necessary to model the displacement of the electrode. This modelling may be performed using finite element analysis software packages, such as Comsol Multiphysics, Ansys or Coventorware, as known to those skilled in the art. Deflection shapes of suitably constrained solid models in response to static or dynamic loading (simulating incident pressure waves causing flexible membrane deflection) may be used to help determine to optimal membrane shape

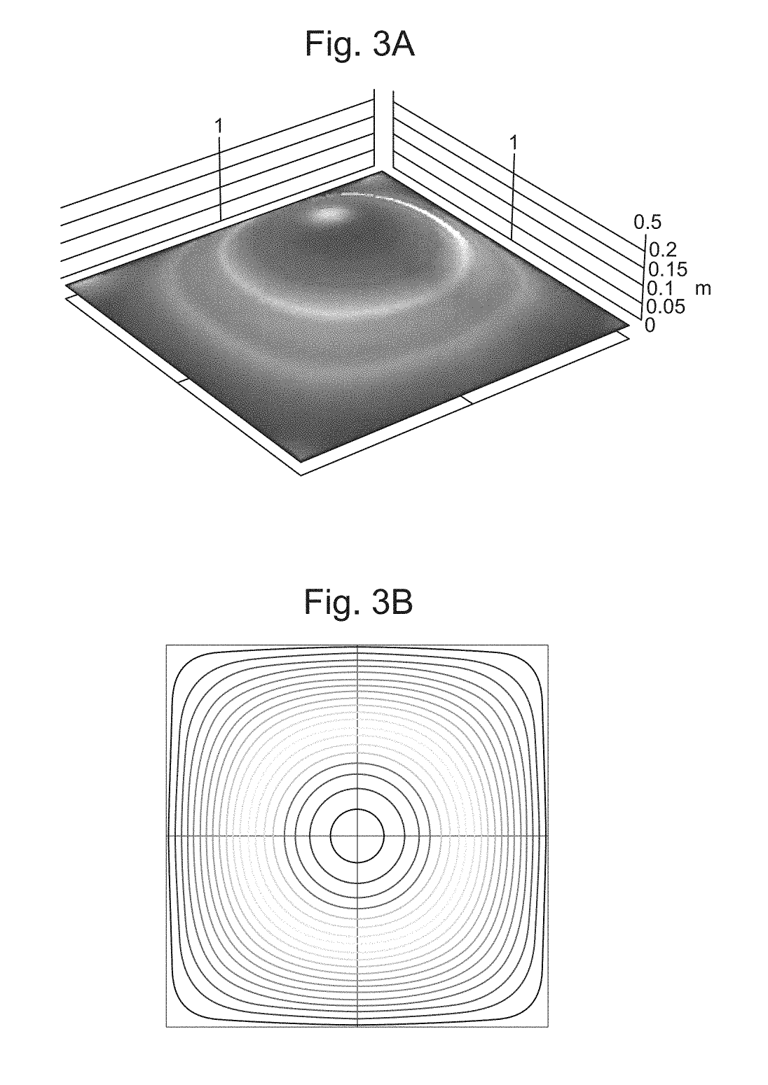

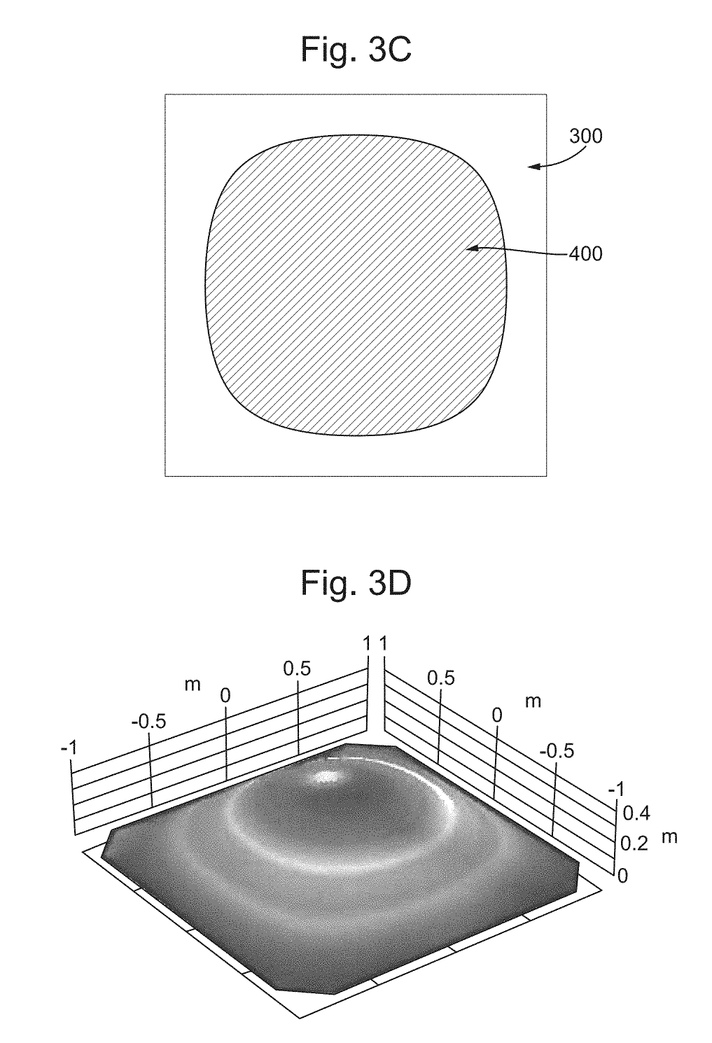

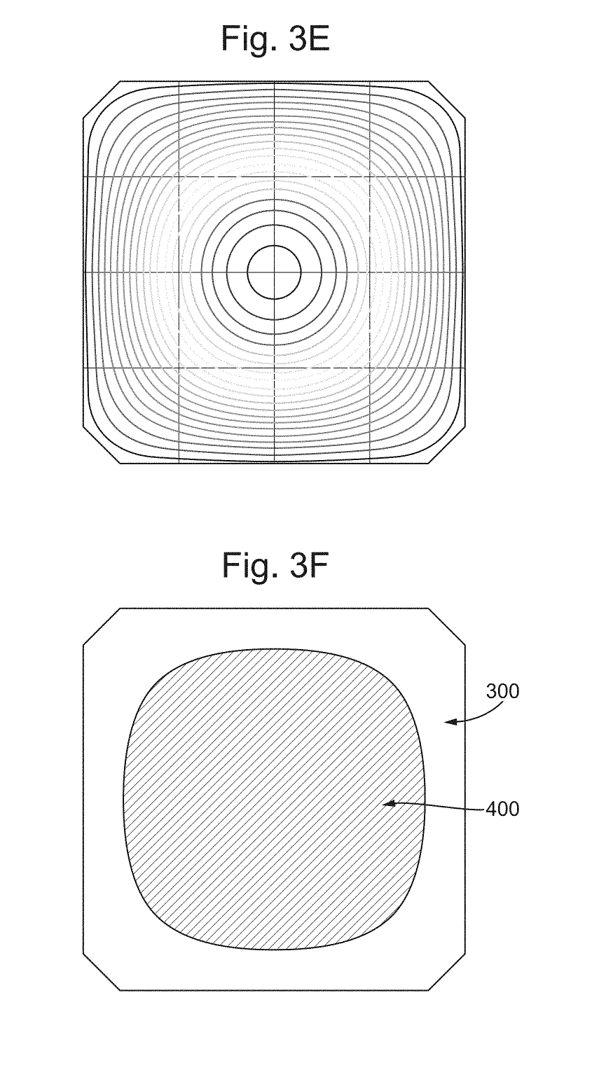

The displacement contours of the flexible membrane are dependent upon the shape of the membrane, the locations at which the edges of the flexible membrane are fixed or free (unfixed), and so on. Where the outline shape of the electrode is configured to correspond to a contour of a contour map of the relative displacement of the flexible membrane, the selection of which contour the outline shape of the electrode should be configured to match is determined by the desired membrane electrode area. This is illustrated by FIGS. 3A to 3C.

FIG. 3A illustrates an example of a simulated displacement for a square flexible membrane that is fixed in position around the entire perimeter of the membrane. The scales on FIG. 3A, and also those on FIGS. 3D, 4A and 5A, use arbitrary units. A plan view of the simulated displacement of FIG. 3A is illustrated in FIG. 3B, which illustrates a contour map showing the displacement contours. Each of the contours connects points of equal displacement relative to a quiescent position. The shade of the contour lines in FIG. 3B corresponds to the shading of the simulated membrane in FIG. 3A. As can be seen from FIGS. 3A and 3B, the contours of equal displacement are not of the same shape as the flexible membrane itself. Instead, and as mentioned above, the shape is determined by factors including the flexible membrane shape and the points at which the membrane is fixed. In this example, the central contours (the membrane displacement is larger near the centre of the membrane) are approximately circular, while the outer contours are rounded squares. Based on the total electrode area desired, a contour may be selected for the outline shape of the membrane electrode. An example of an optimised electrode 400 (configured such that the outline shape of the electrode matches a contour) on a flexible membrane 300 is shown in FIG. 3C.

FIGS. 3D to 3F are equivalent to FIGS. 3A to 3C, but FIGS. 3D to 3F relate to a modified membrane shape. In some aspects, the use of a square membrane (as shown in FIG. 3A to 3C) may not be suitable. The corners of square flexible membranes can be susceptible to damage when the flexible membrane deflects, due to the concentration of force in the corner regions. The modified flexible membrane shape shown in FIGS. 3D to 3F is designed to reduce the possibility of membrane damage by using corners having less acute internal angles. As can be seen from FIGS. 3D to 3F, the flexible membrane has a generally octagonal shape. The flexible membrane may be formed with 4 longer sides and 4 shorter sides, as shown in FIGS. 3D to 3F, so that the flexible membrane occupies a large percentage of the available area of a square space. By shortening the 4 shorter sides, the flexible membrane shape approaches a square flexible membrane, however this results in a concentration of force on the shorter sides. Accordingly, the relative lengths of the longer and shorter sides can be determined based on the expected forces to be applied to the membrane in a given situation.

A plan view of the simulated displacement of FIG. 3D is illustrated in FIG. 3E, which illustrates a contour map showing the displacement contours. As in the case of FIG. 3B, each of the contours of FIG. 3E connects points of equal displacement relative to a quiescent position. The general form of the displacement for the octagonal membrane of FIGS. 3D to 3F is similar to that of the square membrane shown in FIGS. 3A to 3C, and accordingly the shape of the optimised electrode 400 for the octagonal flexible membrane 300 (shown in FIG. 3F) is similar to the optimised electrode shape shown in FIG. 3C.

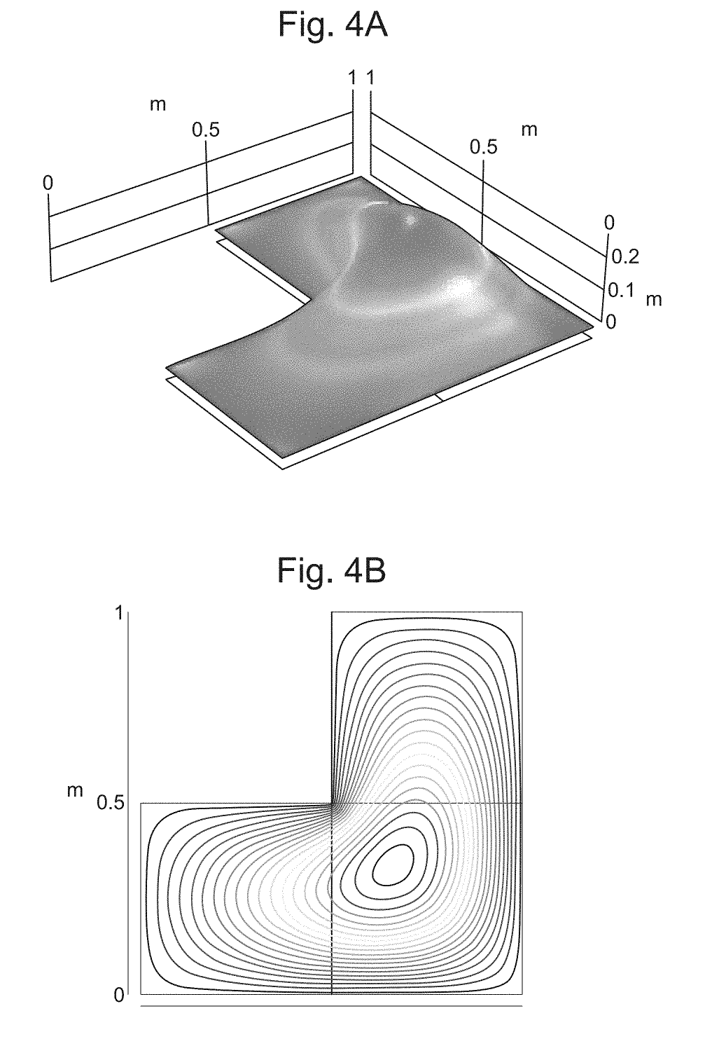

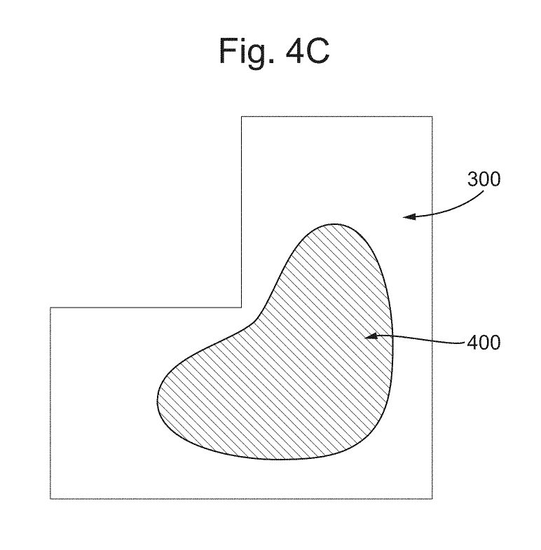

The examples shown in FIGS. 3A to 3F are based on comparatively simple flexible membrane shapes (a square and an octagon). The shape of the flexible membrane used in a given capacitive microphone is determined based on a variety of factors. Two key factors in determining the flexible membrane shape are the shape of the surrounding chip, and chip surface area required for other chip components (such as further sensors, for example). As a result of these considerations, complex flexible membrane shapes may be used for some applications. An example of a more complex shape is shown in FIGS. 4A to 4C. In this example, which is based on the square flexible membrane example shown in FIGS. 3A to 3C, an area of a chip previously used for the flexible membrane is set aside for another purpose (for example, to be occupied by another sensor in a multi-sensor chip). Accordingly, the resulting chip is an irregular hexagon that approximates a reversed “L” shape. Again, the entire perimeter of the flexible membrane is fixed. As can be seen in FIG. 4A, these conditions result in a complex simulated flexible membrane displacement. Analogously to FIG. 3B, a plan view of the simulated displacement showing the displacement contour map can be found in FIG. 4B. Based on the desired electrode area, an optimised electrode shape (configured to correspond to a contour of the displacement map) is selected, as shown in FIG. 4C. In FIG. 4C, the flexible membrane 300 includes the optimised electrode 400.

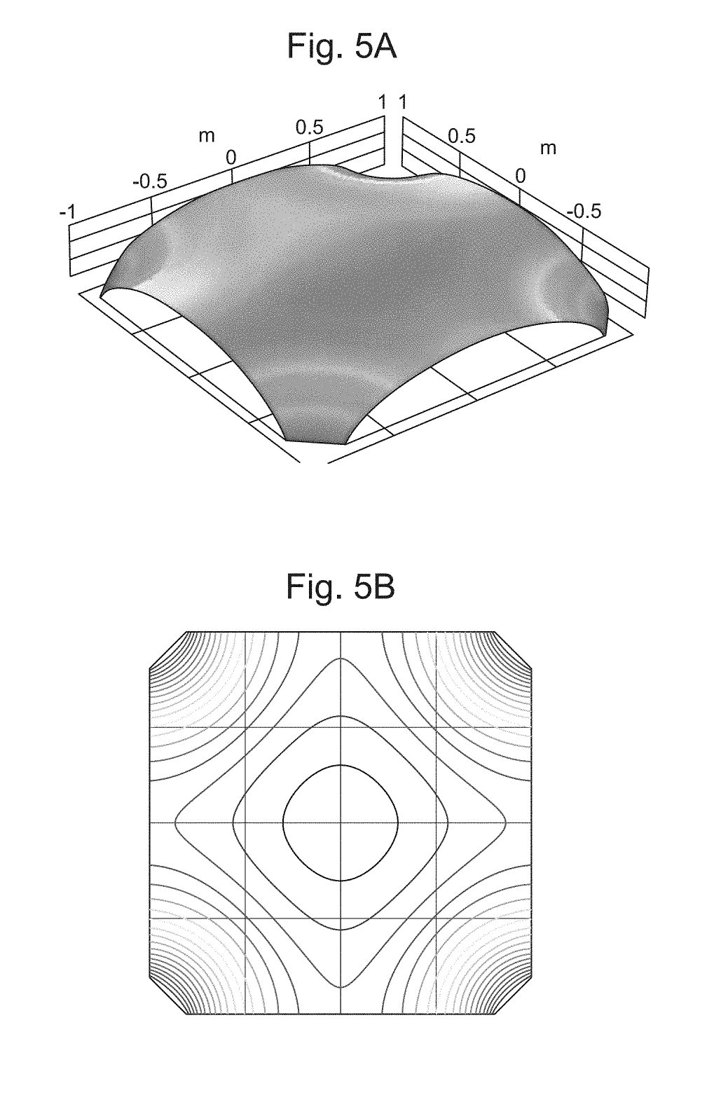

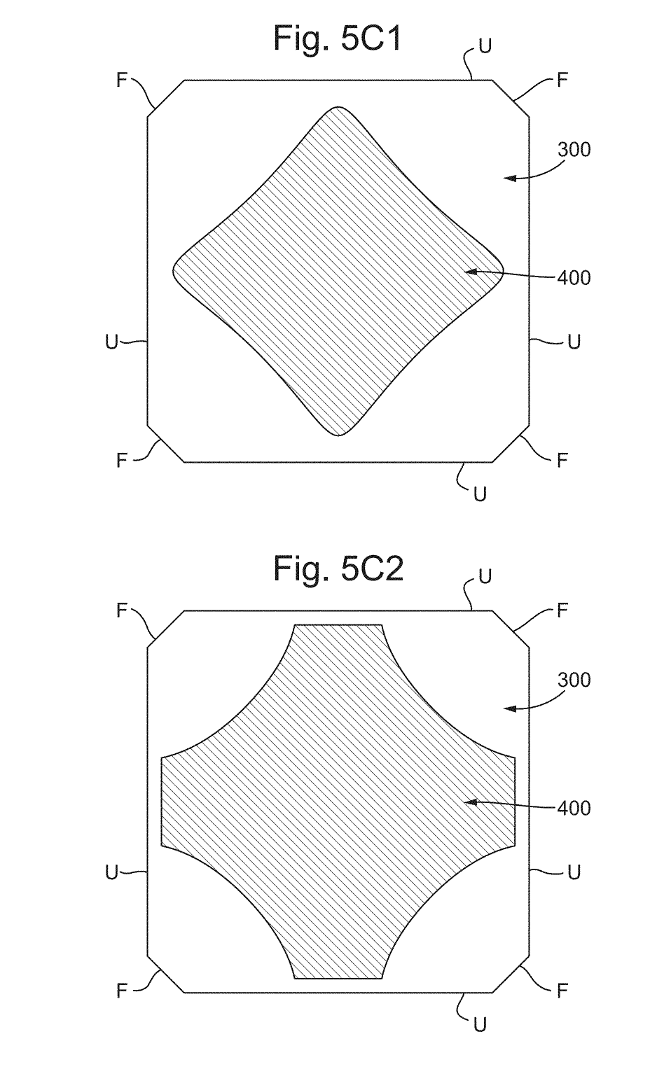

The edges of the flexible membrane may be fixed relative to the remainder of a flexible membrane layer (and also a substrate), as discussed above. Alternatively, some of the edges of the flexible membrane may be unfixed, and the edges may therefore be able to displace relative to a quiescent position when pressure waves are incident upon the flexible membrane. An example of a membrane having fixed and unfixed (free) edges is shown in FIGS. 5A, 5B, 5C1 and 5C2. The outline shape of the flexible membrane is the same as that of the flexible membrane shown in FIGS. 3D to 3F; both flexible membranes are octagonal with 4 shorter edges alternating with 4 longer edges around the perimeter of the flexible membranes. However, while all of the edges of the flexible membrane in FIGS. 3D to 3F are fixed, the 4 longer edges shown in FIG. 5 are unfixed. The unfixed edges may be detached from a membrane layer (which comprises the flexible membrane) in any suitable way. For example, slits in the membrane material may border unfixed edges of the flexible membrane, such that the perimeter of the flexible membrane is defined by one or more fixed edges of the flexible membrane connected to the remainder of the membrane layer and one or more unfixed edges of the flexible membrane. Unfixed edges may be used for various reasons, such as to provide air passages allowing pressure equalisation across the flexible membrane.

The use of unfixed edges significantly alters the displacement of a flexible membrane in response to an incident pressure wave. This is best illustrated by considering the contour maps shown in FIGS. 3E and 5B. The use of unfixed edges typically allows the flexible membrane to displace by a larger amount (on average across the flexible membrane surface) relative to a flexible membrane having only fixed edges. As such, the use of an optimised electrode outline shape can significantly improve the capacitive sensing ability of a system where the flexible membrane has unfixed edges.

FIGS. 5C1 and 5C2 show two different optimised electrode designs, for the same flexible membrane 300. The optimised electrode 400 shown in FIG. 5C1 has a smaller total electrode area than that shown in FIG. 5C2. These Figures illustrate how the selection of a contour from the contour map (using the desired total electrode area) can influence the final shape of the optimised electrode. Total electrode area is a factor that is taken into consideration when designing the optimised electrode. The fixed edges F and unfixed edges U are also shown in FIGS. 5C1 and 5C2.

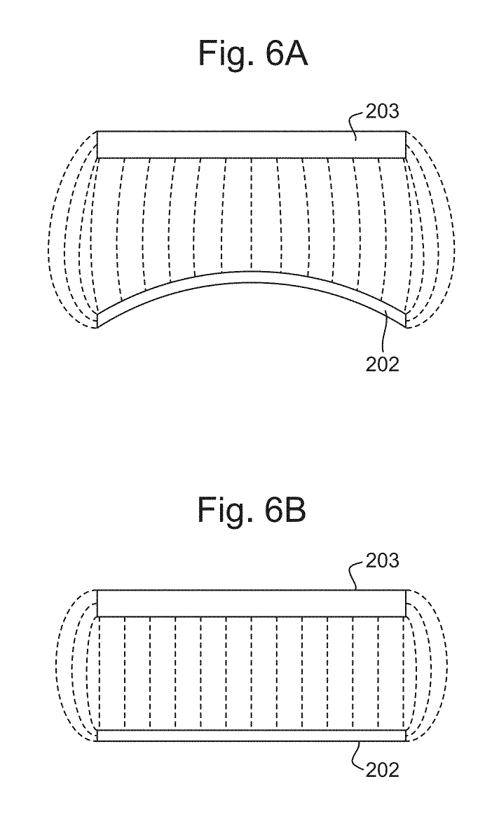

As the displacement of the membrane electrode approaches pistonic displacement (such that the membrane electrode approaches flatness while displaced), the sensitivity of the capacitive sensing which may be performed using the electrode improves. This is because, where the membrane electrode approaches flatness while displaced, the separation between the displaced membrane electrode and the backplate electrode approaches uniformity across the pair of electrodes. Therefore, the variation in sensed capacitance with variation in incident pressure wave magnitude becomes more linear and predictable with increasing flatness. This is illustrated in FIGS. 6A and 6B. FIG. 6A illustrates the electrical field between a (flat) backplate electrode 203 and a membrane electrode 202, wherein the membrane is displaced from an equilibrium position. In FIG. 6A, the membrane electrode 202 is curved (as in the case of FIG. 2A) due to the fixed portions at the edge of the flexible membrane, resulting in non-uniformity of the electrical field between the electrodes as illustrated by the dashed lines in the figure.

FIG. 6B illustrates the electrical field between a (flat) backplate electrode 203 and a membrane electrode 202, wherein the membrane is displaced from an equilibrium position pistonically, such that the membrane electrode remains flat. The flatness of the membrane electrode results in an increased uniformity of the electrical field between the electrodes (relative to the FIG. 6A situation) as illustrated by the dashed lines in the figure.

As can be seen in FIGS. 6A and 6B, the electrical field is densest at points directly between the two electrodes, although edge effects mean that the field also extends to the sides of the electrode (indicated by the curved field lines emitted from the sides of the electrodes not facing the other electrode in FIGS. 6A and 6B). Accordingly, in addition or alternatively to shaping the membrane electrode outline shape to match a displacement contour of the flexible membrane, the uniformity of the field and capacitance variation sensitivity of the system can be improved by shaping the backplate electrode to correspond to a displacement contour of the flexible membrane. That is, the backplate electrode outline shape may be configured to conform to a contour of the flexible membrane, projected onto the backplate, said contour lying directly below the backplate electrode, on a line running perpendicular to the plane of the backplate electrode.

A configuration wherein only the backplate electrode (and not the membrane electrode) is shaped to match a displacement contour of the flexible membrane may be used, for example, if the entire flexible membrane surface is covered in the membrane electrode, or wherein the flexible membrane itself is conductive and acts as the membrane electrode. To still further improve the sensitivity of the system, both the membrane electrode and the backplate electrode may be configured to have outline shapes that follow a contour of the membrane displacement; ideally the same contour but different contours may also be used.

The electrode (either the membrane electrode, backplate electrode or both) is configured such that the electrode outline shape corresponds to a contour of a contour map, the contour map representing relative amounts of displacement of portions of the flexible membrane from an equilibrium position in response to pressure differences generated by incident sound waves. In order to generate the contour map, at least a portion of the MEMS transducer is first simulated. In particular, the flexible membrane is simulated. The flexible membrane may form part of a larger membrane layer, wherein the membrane layer additionally includes portions which are fixed in position (and are used to anchor the membrane layer to the remainder of a MEMS substrate forming part of the MEMS transducer). Other components of the MEMS transducer may also be simulated, such as the backplate.

Once the flexible membrane has been simulated, modelling of the displacement of the simulated flexible membrane in response to incident sound waves is then performed. MEMS transducers are typically formed with a specific purpose in mind (for example, use in a microphone for detecting human speech). As such, a range within which the amplitude and frequency of the incident sound waves to be detected are likely to fall will be know. This information can be used to ensure that the contour map accurately reflects the expected displacement of a flexible membrane generated in accordance with the simulation.

As a result of the dimensions and rigidity of MEMS transducers, typically the frequency with which the flexible membrane may be caused to oscillate by incident sound waves will be below the fundamental resonant frequency of the flexible membrane. This is generally the case where the flexible membrane is intended for use in a microphone for detecting human speech, as mentioned above. However, for some configurations wherein the membrane is larger or less rigid than usual, or the flexible membrane is intended for use in a microphone for detecting very high frequency sounds (such as ultrasound), the frequency with which the flexible membrane may be caused to oscillate by incident pressure waves may be higher than the fundamental resonant frequency of the flexible membrane. Where the expected oscillations of the flexible membrane are above the fundamental resonant frequency of the flexible membrane, this can significantly alter the relative displacements across the flexible membrane (that is, alter the shape of the contour map), and therefore this is taken into consideration when modelling the displacement of the flexible membrane and producing a contour map.

Based on the displacement across the flexible membrane, a contour map is produced as discussed above. This contour map can then be used to design an outline shape for the membrane electrode, the backplate electrode, or both the membrane electrode and backplate electrode. The decision of which contour of the contour map the outline of the electrode or electrodes should be configured to match is made based upon the desired area of the electrodes (and hence capacitive sensing ability of the system).

When the shape of the electrode or electrodes has been finalised, MEMS transducers are produced in accordance with the design. Any suitable method may be used for forming the MEMS transducers, as will be well known to those skilled in the art.

To provide protection the MEMS transducer will typically be contained within a package, forming a MEMS device (also referred to as a packaged MEMS transducer). The package effectively encloses the MEMS transducer and can provide environmental protection and may also provide shielding for electromagnetic interference (EMI) or the like. The package also provides at least one external connection for outputting the electrical signal to downstream circuitry. For microphones and the like the package will typically have a sound port to allow transmission of sound waves to/from the transducer within the package. Various package designs are known, including “lid” type packages and “laminate” type packages.

In a lid type package, a MEMS transducer is mounted to an upper surface of a package substrate. The package substrate may be PCB (printed circuit board) or any other suitable material. A cover or “lid” is located over the transducer and is attached to the upper surface of the package substrate. The cover may be a metallic lid, a plastic lid, and so on. The package typically encloses the MEMS transducer, however when the MEMS device is configured to act as a microphone, an aperture may be included in the package to provide a sound port and allows acoustic signals to enter the package.

An alternative package type, known as a “laminate” type package, comprises operatively constructed and connected printed circuit boards, such as FR-4 boards, that are mechanically and electrically connected together, using techniques that are well known to those skilled in the art. An example laminate type package may include first, second and third members. The first member may comprise a FR-4 board core having metalized tracks, pads, bonds and a solder mask stop layer for example operatively applied to the upper and lower surfaces thereof. The second member may be disposed in a plane overlying the first member and comprise an FR-4 board coated on an inner/lower surface thereof with metalized tracks, pads and a solder stop layer. The third member (or “interposer member”) may be interposed between the first and second members. In this arrangement, the third member forms at least a part of the side walls of the package. The third member can be considered to comprise a cavity or void such that, when the three members are bonded together e.g. by means of solder pads, bonds and through vias, a space is formed between the lower surface of the second member and an upper surface of the first member, wherein the side walls of the space are partially provided by the cavity edges of the third member. A MEMS transducer and an integrated circuit may be provided within the space, i.e. the cavity or void. In this way, the laminate type package encloses the MEMS transducer. As in the case of the lid type package discussed above, the laminate type package may also include an acoustic port where the MEMS device is configured for use as a microphone.

As those skilled in the art will be aware, MEMS transducer die, are typically produced in large wafers, with each wafer often being used to form several thousand MEMS die. With lid type packaging, it is generally necessary after one, or possibly more, MEMS die has been attached to the package substrate (usually FR4), to attach a lid individually over each MEMS transducer die to form each packaged MEMS transducer, i.e. MEMS device. By contrast, the triple layer structure of the laminate packaging allows all of the MEMS devices to be constructed using combined processes (for example, sealing the interposed layer between the first layer and second layer), before the panel is divided into individual MEMS devices. Using a larger number of combined processes to form the MEMS devices in this way significantly reduces the time and expense relative to the use of lid type packaging; this is commonly referred to as parallel processing.

The flexible membrane may comprise a crystalline or polycrystalline material, such as one or more layers of silicon-nitride Si₃N₄.

MEMS transducers according to the present examples will typically be associated with circuitry for processing an electrical signal generated as a result of detected movement of the flexible membrane, either by a capacitive sensing technique or by an optical sensing technique. Thus, in order to process an electrical output signal from the microphone, the transducer die/device may have circuit regions that are integrally fabricated using standard CMOS processes on the transducer substrate.

The circuit regions may be fabricated in the CMOS silicon substrate using standard processing techniques such as ion implantation, photomasking, metal deposition and etching. The circuit regions may comprise any circuit operable to interface with a MEMS transducer and process associated signals. For example, one circuit region may be a pre-amplifier connected so as to amplify an output signal from the transducer. In addition another circuit region may be a charge-pump that is used to generate a bias, for example 12 volts, across the two electrodes. This has the effect that changes in the electrode separation (i.e. the capacitive plates of the microphone) change the MEMS microphone capacitance; assuming constant charge, the voltage across the electrodes is correspondingly changed. A pre-amplifier, preferably having high impedance, is used to detect such a change in voltage.

The circuit regions may optionally comprise an analogue-to-digital converter (ADC) to convert the output signal of the microphone or an output signal of the pre-amplifier into a corresponding digital signal, and optionally a digital signal processor to process or part-process such a digital signal. Furthermore, the circuit regions may also comprise a digital-to-analogue converter (DAC) and/or a transmitter/receiver suitable for wireless communication. However, it will be appreciated by one skilled in the art that many other circuit arrangements operable to interface with a MEMS transducer signal and/or associated signals, may be envisaged.

It will also be appreciated that, alternatively, the microphone device may be a hybrid device (for example whereby the electronic circuitry is totally located on a separate integrated circuit, or whereby the electronic circuitry is partly located on the same device as the microphone and partly located on a separate integrated circuit) or a monolithic device (for example whereby the electronic circuitry is fully integrated within the same integrated circuit as the microphone).

Examples described herein may be usefully implemented in a range of different material systems, however the examples described herein are particularly advantageous for MEMS transducers having membrane layers comprising silicon nitride.

It is noted that the example embodiments described above may be used in a range of devices, including, but not limited to: analogue microphones, digital microphones, pressure sensor or ultrasonic transducers. The example embodiments may also be used in a number of applications, including, but not limited to, consumer applications, medical applications, industrial applications and automotive applications. For example, typical consumer applications include portable audio players, laptops, mobile phones, PDAs and personal computers. Example embodiments may also be used in voice activated or voice controlled devices. Typical medical applications include hearing aids. Typical industrial applications include active noise cancellation. Typical automotive applications include hands-free sets, acoustic crash sensors and active noise cancellation.

Features of any given aspect or example embodiment may be combined with the features of any other aspect or example embodiment and the various features described herein may be implemented in any combination in a given embodiment.

Associated methods of fabricating a MEMS transducer are provided for each of the example embodiments.

It should be understood that the various relative terms above, below, upper, lower, top, bottom, underside, overlying, underlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

In the examples described above it is noted that references to a transducer may comprise various forms of transducer element. For example, a transducer may be typically mounted on a die and may comprise a single membrane and back-plate combination. In another example a transducer die comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprise different individual transducers positioned to receive acoustic signals from different acoustic channels.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A MEMS transducer comprising a flexible membrane and a backplate,
a membrane electrode being located on a polygon shaped first surface of the flexible membrane, and a backplate electrode being located on a first surface of the backplate facing the membrane electrode,
wherein at least one of the membrane electrode and the backplate electrode has an outline shape configured to correspond to a contour of a contour map, the contour map representing relative amounts of displacement of portions of the flexible membrane from an equilibrium position in response to pressure differences generated by incident sound waves.

2. The MEMS transducer of claim 1, wherein the outline shape corresponds to a contour representing points of the flexible membrane of equal displacement from the equilibrium position.

3. The MEMS transducer of claim 1, further comprising a substrate and a membrane layer, the membrane layer comprising the flexible membrane.

4. The MEMS transducer of claim 3, wherein the perimeter of the flexible membrane is defined by a fixed edge of the flexible membrane connected to the substrate.

5. The MEMS transducer of claim 3, wherein membrane layer comprises one or more slits which border unfixed edges of the flexible membrane, such that the perimeter of the flexible membrane is defined by one or more fixed edges of the flexible membrane connected to the substrate and one or more unfixed edges of the flexible membrane.

6. The MEMS transducer of claim 1, wherein the first surface of the flexible membrane is rectangular, optionally wherein the first surface of the flexible membrane is square.

7. The MEMS transducer of claim 1, wherein the first surface of the flexible membrane is octagonal.

8. The MEMS transducer of claim 7, wherein the first surface of the flexible membrane is an octagon having edges of a first length and edges of a second length, the edges of the first length and the edges of the second length alternating around the perimeter of the first surface of the flexible membrane.

9. The MEMS transducer of claim 1, wherein:
the membrane electrode has an outline shape configured to correspond to the contour of the contour map; and
the outline shape of the membrane electrode is selected such that the volume displaced by the membrane electrode, when the maximum membrane displacement distance from an equilibrium position is 10% of the mean diameter of the first surface of the flexible membrane, is at least 80% of the volume displaced by an identical electrode displaced pistonically by the maximum membrane displacement distance.

10. The MEMS transducer of claim 1, wherein the contour map represents the relative amounts of displacement of portions of the flexible membrane from the equilibrium position in response to pressure differences generated by sound waves having a frequency which is lower than the fundamental resonant frequency of the flexible membrane.

11. The MEMS transducer of claim 1, wherein the contour map represents the relative amounts of displacement of portions of the flexible membrane from the equilibrium position in response to pressure differences generated by sound waves having a frequency which is equal to or higher than the fundamental resonant frequency of the flexible membrane.

12. A method of forming a MEMS transducer comprising a flexible membrane and a backplate, a membrane electrode being located on a polygon shaped first surface of the flexible membrane, and a backplate electrode being located on a first surface of the backplate facing the membrane electrode, the method comprising:
simulating the flexible membrane of the MEMS transducer;
modelling the displacement of the simulated flexible membrane in response to pressure differences generated by incident sound waves;
producing a contour map representing relative amounts of displacement of portions of the flexible membrane from an equilibrium position in response to pressure differences generated by incident sound waves;
designing an outline shape of at least one of the membrane electrode and the backplate electrode to correspond to a contour of the contour map; and
producing the MEMS transducer in accordance with the design.

13. A MEMS transducer comprising:
a polygon shaped flexible membrane; and
a membrane electrode located on a surface of the flexible membrane,
wherein the membrane electrode is shaped to substantially correspond to a contour of a contour map, the contour map representing relative amounts of displacement of portions of the flexible membrane from an equilibrium position in response to incident pressure waves.

14. (canceled)

15. (canceled)

16. A packaged MEMS microphone comprising the MEMS transducer of claim 1.

17. An electronic device comprising the MEMS transducer of claim 1.
